(19) United States
(12) Patent Application Publication
(10) Pub. No.: US 2009/0293937 A1
(43) Pub. Date: Dec. 3, 2009

(54) DEVICE FOR THE INDIRECT FREQUENCY-SELECTIVE ILLUMINATION OF SOLAR CELLS

(75) Inventor: Hubert STIEHLE, Tettnang (DE)

Correspondence Address: GREENBLUM & BERNSTEIN, P.L.C., 1950 ROLAND CLARKE PLACE, RESTON, VA, 20191, US

(73) Assignee: ASTRIUM GMBH, Muenchen (DE)

(21) Appl. No.: 12/472,928

(22) Filed: May 27, 2009

(30) Foreign Application Priority Data
May 28, 2008 (DE) 102008025644.7-54

(51) Int. Cl. B64G 1/44; H01L 31/042; H01L 31/00

(52) U.S. Cl. 136/246; 136/252; 244/172.8

(57) ABSTRACT

Apparatus, satellite, and method for illumination of at least one solar cell. Apparatus includes at least one solar cell and at least one optical device structured and arranged for an indirect frequency-selective illumination of the at least one solar cell. The at least one optical device reflects spectral components relevant for energy conversion onto the solar cells and guides the spectral components not relevant for energy conversion away from the solar cells.

### CROSS-REFERENCE TO RELATED APPLICATIONS

The present application claims priority under 35 U.S.C. §119 of German Patent Application No. DE 10 2008 025 644.7-54 filed May 28, 2008, the disclosure of which is expressly incorporated by reference herein in its entirety.

### BACKGROUND OF THE INVENTION

1. Field of the Invention

The invention relates to a device for the indirect frequency-selective illumination of solar cells.

2. Discussion of Background Information

Direct exposure of solar cells to a light source is known from the prior art. This direct exposure can have the disadvantage that overheating of the solar cells easily occurs, in particular in regions with high spectral power flux density, such as, e.g., satellite orbits close to the sun. With conventional technology, the solar cells would have to be aligned markedly <90° to the sun, which leads to a reduction in efficiency due to suboptimal utilization of the solar spectrum. In the case of temporary loss of control of the satellite, the solar cells can nevertheless overheat.

### SUMMARY OF THE INVENTION

The invention provides a device structured so that the risk of overheating due to high spectral power density is reduced.

The invention describes a device including several solar cells. An indirect frequency-selective illumination of the solar cells takes place using optical devices, which reflect the spectral components relevant for energy conversion onto the solar cells and guide the not relevant spectral component away from the solar cells.

For the invention according to one embodiment, in particular optical filters can be selected for the optical devices.

According to another embodiment, in particular semitransparent mirrors can be used for the optical devices.

According to a further embodiment, the semitransparent mirrors can be films or glasses coated with reflecting substances.

According to a further embodiment, the spectral components below approx. 700 nm can be relevant.

According to a further embodiment, the non-relevant spectral components can be infrared components and can be guided into free space or into other absorbing media.

According to a further embodiment, the one or the several frequency-selective mirrors can be positioned at an angle of approx. 45° to the solar radiation or to the referenced cells.

According to a further embodiment, in the case of loss of control the one or the several frequency-selective mirrors can be pivoted back into the direction of the surface of the solar cells again in order to protect them from overheating.

Advantages of the invention are the reduction of the temperature of the solar cells and an increase of efficiency through an increase of the efficiency of the solar cells and a saving of solar generator surface area.

Embodiments of the invention are directed to an apparatus that includes at least one solar cell and at least one optical device structured and arranged for an indirect frequency-selective illumination of the at least one solar cell. The at least one optical device reflects spectral components relevant for energy conversion onto the solar cells and guides the spectral components not relevant for energy conversion away from the solar cells.

According to embodiments, the at least one optical device can include at least one optical filter.

In accordance with other embodiments of the instant invention, the at least one optical device may include at least one semitransparent mirror. The at least one semitransparent mirror can include at least one of films or glasses coated with reflecting substances.

Further, the relevant spectral components can include spectral components below approx. 700 nm, and the non-relevant spectral components may include infrared components. The non-relevant spectral components may be guided into at least one of free space or into other absorbing media.

According to further embodiments, the at least one optical device can be oriented at an angle of approx. 45° to at least one of a solar radiation source and to the at least one solar cell.

In accordance with other embodiments of the present invention, the at least one optical device can include at least two optical devices, each oriented at an angle of approx. 45° to at least one of a solar radiation source and to the at least one solar cell.

Still further, the apparatus can include overheating protection in which, in an event of loss of control, the at least one optical device is pivotable toward a surface of the at least one solar cell.

Embodiments of the invention are directed to a method of illuminating a solar generator that includes at least one solar cell. The method includes positioning at least one optical device to indirectly illuminate the at least one solar cell with spectral components relevant for energy conversion and to pass spectral components not relevant for energy conversion.

In accordance with embodiments of the instant invention, the at least one optical device can include at least one optical filter, at least one semitransparent mirror, and/or at least one of a reflecting glass or reflecting film.

Moreover, the spectral components relevant to energy conversion can be less than approximately 700 nm and the spectral components not relevant to energy conversion can include infrared components.

According to other embodiments of the invention, the positioning may include orienting the at least one optical device about 45° to at least one of a solar radiation source and to a surface of the at least one solar cell.

In accordance with additional embodiments, the method can include pivoting the least one optical device from a position for indirectly illuminating the at least one solar cell into a direction of a surface of the at least one solar cell. The pivoting may occur as a result of a loss of control.

According to embodiments, a satellite includes at least one solar generator comprising at least one solar cell, and at least one indirect frequency-selective illuminator positionable to illuminate the at least one solar cell with spectral components relevant for energy conversion, while passing spectral components not relevant for energy conversion.

In accordance with still yet other embodiments of the present invention, the at least one solar generator may include at least two solar generators and the at least one indirect frequency-selective illuminator may include at least two indirect frequency-selective illuminators. Further, the at least two solar generators can be arranged back to back so that front surfaces of the at least two solar generator face in opposite directions, and the at least two indirect frequency-selective illuminators can be obliquely oriented over the front surfaces of the at least two solar generators.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates an arrangement according to embodiments of the invention with two solar generators; and

FIG. 2 illustrates an arrangement according to other embodiments of the invention with one solar generator.

### DETAILED DESCRIPTION OF THE PRESENT INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

Advantages of the invention are the reduction of the temperature of the solar cells and an increased efficiency through an increase in the efficiency of the solar cells and a saving of solar generator surface area. The operation of solar generators in orbits close to the sun can also be made possible for the first time by the invention.

To increase the efficiency of solar cells and to reduce the temperature of the solar cells, specifically with high power flux densities, such as, e.g., in satellite orbits close to the sun, embodiments of the invention provides for the spectral components of light relevant for energy conversion to exclusively reach the cells.

According to the invention, this is realized through the use of one or more frequency-selective mirrors. These mirrors act in a reflecting manner for the desired and used (relevant) spectral components and in a transparent manner for the other (non-relevant) spectral components, e.g., infrared. The one or the several frequency-selective mirrors are thereby positioned at an angle of approx. 45° to the solar radiation or to the referenced cells. The spectral components converted by the solar generator into thermal radiation can likewise be emitted again by the mirrors.

Embodiments of the invention are advantageous in that efficiency of the solar increases while the working temperature is reduced.

Films coated with reflecting substances, e.g., thin MYLAR/Kapton films or similar even more heat-resistant films or glasses, can be used as mirrors, in order to reflect the spectral components (below 700 nm) relevant for energy conversion onto the solar cells and to emit the infrared components (above 700 nm) into free (cold) space or to guide them into other absorbing media.

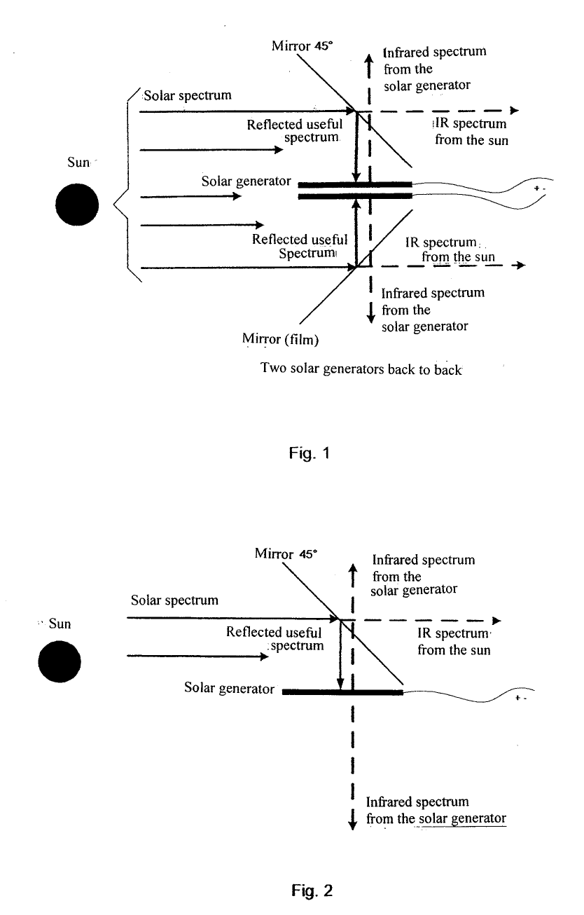

FIG. 1 clarifies the arrangement according to the invention. FIG. 1 shows a maximum configuration with two solar generators back to back. However, the invention is not restricted to two solar generators, but can comprise any number of pairs of solar generators. The invention is described based on one pair of solar generators only to simplify matters.

The generators, which include one or more solar cells, are aligned parallel to the sun. In front of each solar generator a semipermeable filter mirror is located folded away therefrom at an angle of approx. 45°. The mirror is permeable for the infrared spectrum but reflects a useful spectrum mainly in the visible range approximately perpendicularly onto the surface of the solar generators.

The dissipated heat of the generators can likewise be emitted as infrared radiation through the mirrors (approx. 90° to the sun).

FIG. 2 shows a simplified panel arrangement. Only an arrangement with respectively one solar generator and one filter mirror can be used for applications that are even more critical in terms of temperature than those described above. The rear side of the solar generator is also hereby used for emitting the dissipated heat.

For both of the embodiments described above, in the event of loss of control the one or the several frequency-selective mirrors can be pivoted back into the direction of the surface of the solar cells again in order to protect from overheating.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed:

1. An apparatus comprising:
at least one solar cell;
at least one optical device structured and arranged for an indirect frequency-selective illumination of the at least one solar cell,
wherein the at least one optical device reflects spectral components relevant for energy conversion onto the solar cells and guides the spectral components not relevant for energy conversion away from the solar cells.

2. The apparatus in accordance with claim 1, wherein the at least one optical device comprises at least one optical filter.

3. The apparatus in accordance with claim 1, wherein the at least one optical device comprises at least one semitransparent mirror.

4. The apparatus in accordance with claim 3, wherein the at least one semitransparent mirror comprises at least one of films or glasses coated with reflecting substances.

5. The apparatus in accordance with claim 1, wherein the relevant spectral components comprise spectral components below approx. 700 nm.

6. The apparatus in accordance with claim 1, wherein the non-relevant spectral components comprise infrared components.

7. The apparatus in accordance with claim 6, wherein the non-relevant spectral components are guided into at least one of free space or into other absorbing media.

8. The apparatus in accordance with claim 1, wherein the at least one optical device is oriented at an angle of approx. 45° to at least one of a solar radiation source and to the at least one solar cell.

9. The apparatus in accordance with claim 1, wherein the at least one optical device comprises at least two optical devices, each oriented at an angle of approx. 45° to at least one of a solar radiation source and to the at least one solar cell.

10. The apparatus in accordance with claim 1, further comprising overheating protection in which, in an event of loss of control, the at least one optical device is pivotable toward a surface of the at least one solar cell.

11. A method of illuminating a solar generator comprising at least one solar cell, the method comprising:
positioning at least one optical device to indirectly illuminate the at least one solar cell with spectral components relevant for energy conversion and to pass spectral components not relevant for energy conversion.

12. The method in accordance with claim 11, wherein the at least one optical device comprises at least one optical filter.

13. The method in accordance with claim 11, wherein the at least one optical device comprises at least one semitransparent mirror.

14. The method in accordance with claim 11, wherein the at least one optical device comprises at least one of a reflecting glass or reflecting film.

15. The method in accordance with claim 11, wherein the spectral components relevant to energy conversion are less than approximately 700 nm and the spectral components not relevant to energy conversion comprise infrared components.

16. The method in accordance with claim 11, wherein the positioning comprises orienting the at least one optical device about 45° to at least one of a solar radiation source and to a surface of the at least one solar cell.

17. The method in accordance with claim 11, further comprising pivoting the least one optical device from a position for indirectly illuminating the at least one solar cell into a direction of a surface of the at least one solar cell.

18. The method in accordance with claim 17, wherein the pivoting occurs as a result of a loss of control.

19. A satellite comprising:
at least one solar generator comprising at least one solar cell; and
at least one indirect frequency-selective illuminator positionable to illuminate the at least one solar cell with spectral components relevant for energy conversion, while passing spectral components not relevant for energy conversion.

20. The satellite in accordance with claim 19, wherein the at least one solar generator comprises at least two solar generators and the at least one indirect frequency-selective illuminator comprises at least two indirect frequency-selective illuminators, and
wherein the at least two solar generators are arranged back to back so that front surfaces of the at least two solar generator face in opposite directions, and the at least two indirect frequency-selective illuminators are obliquely oriented over the front surfaces of the at least two solar generators.
